(19) United States
(12) Patent Application Publication
(10) Pub. No.: US 2014/0170301 A1
(43) Pub. Date: Jun. 19, 2014

(54) THIN FILM DEPOSITION APPARATUS AND METHOD

(71) Applicant: SAMSUNG DISPLAY CO., LTD., Yongin-city (KR)

(72) Inventors: Yong Hun Jo, Yongin-city (KR); Jae Hong Ahn, Yongin-city (KR); Jong Woo Lee, Yongin-city (KR)

(73) Assignee: Samsung Display co., Ltd., Yongin-city (KR)

(21) Appl. No.: 13/797,573

(22) Filed: Mar. 12, 2013

(30) Foreign Application Priority Data
Dec. 18, 2012 (KR) 10-2012-0148878

(51) Int. Cl. C23C 16/52

(52) U.S. Cl. CPC C23C 16/52
USPC 427/9; 118/712

(57) ABSTRACT

A thin film deposition apparatus and method are disclosed. In one aspect, the deposition apparatus comprises a deposition source emitting a deposition material that is to be deposited on a surface of a substrate, a transfer unit moving the deposition source, a thickness measurement sensor measuring a thickness of the deposition material deposited on the surface of the substrate, and a transfer controller adjusting a moving speed of the transfer unit according to the thickness of the deposition material deposited on the surface of the substrate per unit of time.

This application claims priority from Korean Patent Application No. 10-2012-0148878 filed on Dec. 18, 2012 in the Korean Intellectual Property Office, the disclosure of which is incorporated herein by reference in its entirety.

### BACKGROUND

1. Field

The disclosed technology relates to a deposition apparatus and method.

2. Description of the Related Technology

A thin film deposition process is generally included in the process of manufacturing a display, a semiconductor integrated circuit, a solar cell, etc. For example, multiple thin films included in a liquid crystal display (LCD), a field emission display, a plasma display, an electroluminescence display such as one using organic light emitting diodes (OLEDs), or the like are formed by a deposition process.

Of various types of deposition processes, a vapor deposition process for forming a thin film on a substrate by evaporating a deposition material is performed in a vacuum deposition chamber, mostly based on a thermal deposition process. That is, a substrate is installed inside the vacuum deposition chamber and a deposition source is installed to face a surface of the substrate. Then, the deposition material contained in the deposition source is heated so that the deposition material evaporates. As the deposition material in a gaseous state reaches the substrate in a vacuum, it hardens and a thin film is formed on the substrate.

When a thin film is formed on a substrate by vapor deposition, it becomes necessary to adjust the thickness of the thin film. That is, the thin film thickness needs to be either uniform or non-uniform according to desired device characteristics.

### SUMMARY OF CERTAIN INVENTIVE ASPECTS

Aspects of the disclosed technology include a deposition apparatus which can adjust a thickness of a thin film deposited on a surface of a substrate during a deposition process without releasing vacuum.

Aspects of the disclosed technology also include a deposition method in which a thickness of a thin film deposited on a surface of a substrate can be adjusted during a deposition process without release of vacuum.

However, aspects of the disclosed technology are not restricted to the one set forth herein. The above and other aspects of the disclosed technology will become more apparent to one of ordinary skill in the art to which the disclosed technology pertains by referencing the detailed description of the disclosed technology given below.

According to an aspect of the disclosed technology, there is a thin film deposition apparatus, comprising: a deposition source configured to emit a deposition material that is to be deposited on a surface of a substrate, a transfer unit configured to move the deposition source, a thickness measurement sensor configured to measure a thickness of the deposition material deposited on the surface of the substrate, and a transfer controller configured to adjust a moving speed of the transfer unit according to the thickness of the deposition material deposited on the surface of the substrate per unit of time.

According to another aspect of the disclosed technology, there is a thin film deposition apparatus, comprising: a deposition source configured to emit a deposition material that is to be deposited on a surface of a substrate, at least one shutter configured to adjust an emission region of the deposition material by opening or closing at least part of an emission path of the deposition material, a thickness measurement sensor configured to measure a thickness of the deposition material deposited on the surface of the substrate, and a shutter controller configured to control the shutter according to the measured thickness of the deposition material.

According to still another aspect of the disclosed technology, there is a thin film deposition method, comprising: emitting a deposition material, which is to be deposited on a surface of a substrate, using a deposition source, measuring a thickness of the deposition material deposited on the surface of the substrate, moving the deposition source across the substrate, and adjusting the speed of the deposition source movement according to the thickness of the deposition material deposited on the surface of the substrate per unit of time.

According to still another aspect of the disclosed technology, there is a deposition method, comprising: forming a first thin film on a first substrate by moving a deposition source at a first speed, and forming a second thin film, which has the same thickness as the first thin film, on a second substrate by moving the deposition source at a second speed which is different from the first speed.

### BRIEF DESCRIPTION OF THE DRAWINGS

The above and other aspects and features of the disclosed technology will become more apparent by describing in detail exemplary embodiments thereof with reference to the attached drawings, in which:

FIG. 1 is a perspective view of a deposition apparatus according to an embodiment of the disclosed technology;

FIG. 2 is a side view of the deposition apparatus shown in FIG. 1;

FIG. 3 is a block diagram of a transfer controller and a shutter controller included in the deposition apparatus of FIG. 1;

FIG. 4 is a schematic diagram showing respective thicknesses of thin films formed on a plurality of substrates in a configuration where a moving speed of a transfer unit included in the deposition apparatus of FIG. 1 is not adjusted;

FIG. 5 is a schematic diagram showing respective thicknesses of thin films formed on a plurality of substrates in a configuration where the moving speed of the transfer unit included in the deposition apparatus of FIG. 1 is adjusted;

FIG. 6 is a schematic diagram showing a thickness of a thin film formed on one substrate in a configuration where the moving speed of the transfer unit included in the deposition apparatus of FIG. 1 is not adjusted;

FIG. 7 is a schematic diagram showing a thickness of a thin film formed on one substrate in a case where the moving speed of the transfer unit included in the deposition apparatus of FIG. 1 is adjusted;

FIG. 8 shows graphs of the green color coordinate with respect to deposition rate before and after the moving speed of the transfer unit included in the deposition apparatus of FIG. 1 is adjusted;

FIG. 9 is a plan view of a first application example of a deposition source, the transfer unit, and a shutter included in the deposition apparatus of FIG. 1;

FIG. 10 is a schematic diagram illustrating the thin-film thickness with respect to distance before the shutter of FIG. 9 is applied;

FIG. 11 is a schematic diagram illustrating the thin-film thickness with respect to distance after the shutter of FIG. 9 is applied;

FIG. 12 is a plan view of a second application example of the deposition source, the transfer unit, and the shutter included in the deposition apparatus of FIG. 1;

FIG. 13 is a schematic diagram illustrating the thin-film thickness with respect to distance before the shutter of FIG. 12 is applied;

FIG. 14 is a schematic diagram illustrating the thin-film thickness with respect to distance after the shutter of FIG. 12 is applied;

FIG. 15 is a block diagram of a transfer controller and a shutter controller included in a deposition apparatus according to another embodiment of the disclosed technology;

FIGS. 16 and 17 are plan views of deposition sources, transfer units, and shutters included in deposition apparatuses according to other embodiments of the disclosed technology; and

FIG. 18 is a cross-sectional view of the shutter taken along the line A-A′ of FIG. 17.

### DETAILED DESCRIPTION OF CERTAIN INVENTIVE EMBODIMENTS

The aspects and features of the disclosed technology and methods for achieving the aspects and features will be apparent by referring to the embodiments to be described in detail with reference to the accompanying drawings. However, disclosed embodiments, but can be implemented in diverse forms and are not limiting. The matters defined in the description, such as the detailed construction and elements, are nothing but specific details provided to assist those of ordinary skill in the art in a comprehensive understanding of the invention, and the present invention is only defined within the scope of the appended claims.

The term “on” that is used to designate that an element is on another element or located on a different layer or a layer includes both a configuration where an element is located directly on another element or a layer and a case where an element is located on another element via another layer or still another element. In the entire description of the present invention, the same drawing reference numerals are used for the same elements across various figures.

Although the terms “first, second, and so forth” are used to describe diverse constituent elements, such constituent elements are not limited by the terms. The terms are used only to discriminate a constituent element from other constituent elements. Accordingly, in the following description, a first constituent element may be a second constituent element.

Hereinafter, embodiments of the disclosed technology will be described with reference to the attached drawings.

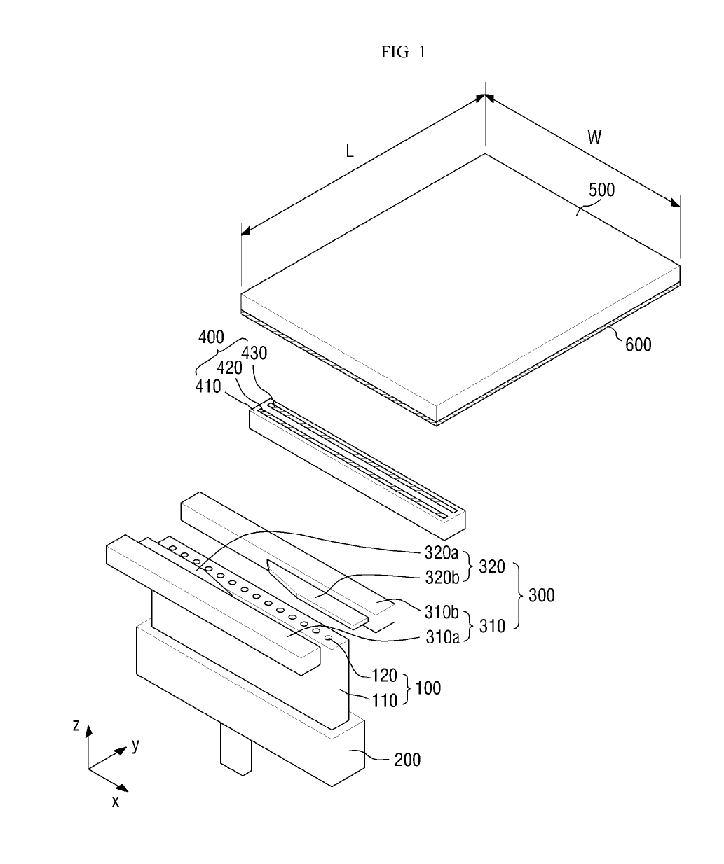

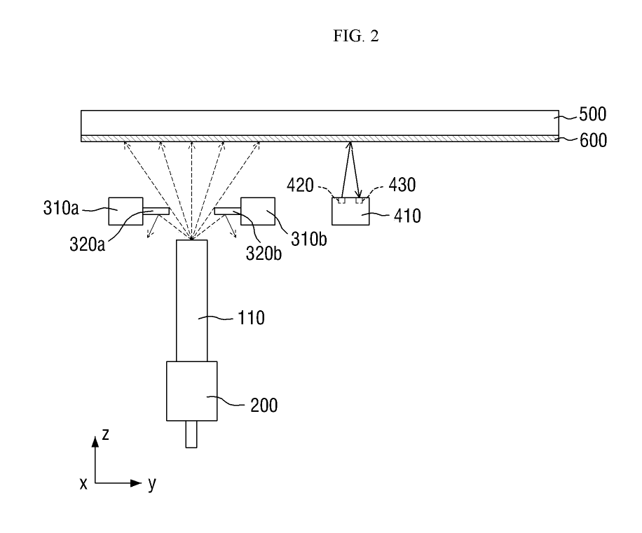

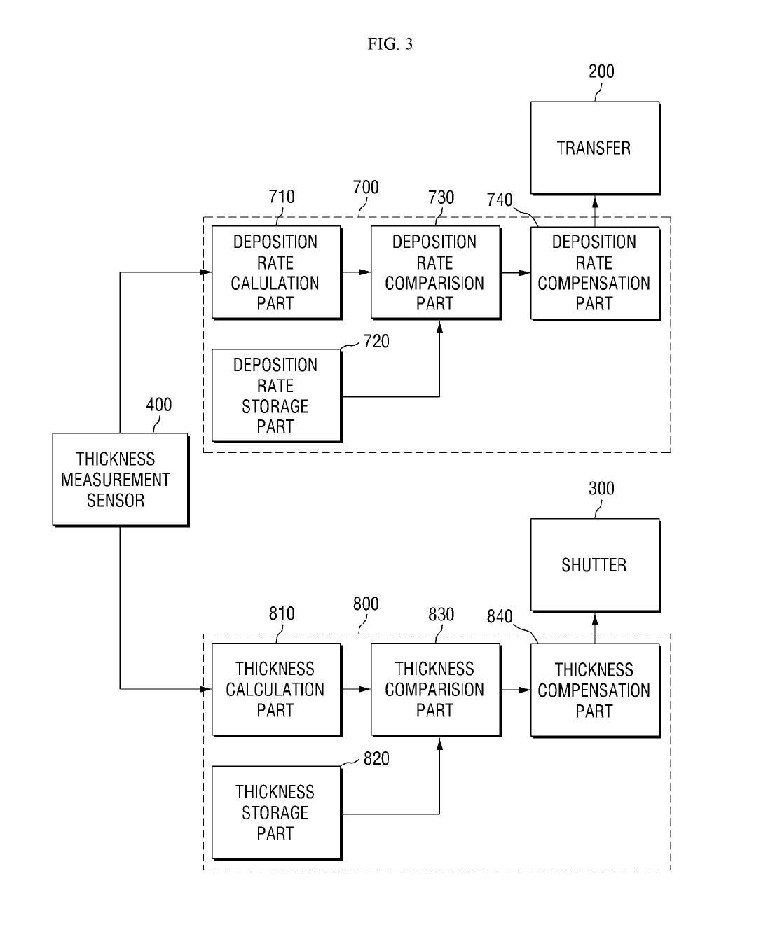

FIG. 1 is a perspective view of a thin film deposition apparatus according to an embodiment of the disclosed technology. FIG. 2 is a side view of the deposition apparatus shown in FIG. 1. FIG. 3 is a block diagram of a transfer controller 700 and a shutter controller 800 included in the deposition apparatus of FIG. 1. Referring to FIGS. 1 through 3, the deposition apparatus may include a deposition source 100, a transfer unit 200, a thickness measurement sensor 400, and the transfer controller 700. In addition, the deposition apparatus may include a shutter 300 and the shutter controller 800.

The thin film deposition apparatus can be used in the process of manufacturing a display, a semiconductor integrated circuit, a solar cell, etc. For example, the deposition apparatus can be used in the process of forming a plurality of thin films 600 included in a liquid crystal display (LCD), a field emission display, a plasma display, an electroluminescence display such as one using organic light emitting diodes (OLEDs), or the like.

The deposition apparatus typically includes a deposition chamber (not shown). The deposition chamber will often maintain a vacuum during thin film deposition. To maintain the vacuum, the deposition chamber may include at least one vacuum pump, for example, a cryopump. In typical embodiments, the deposition source 100, the transfer unit 200, the shutter 300, and the thickness measurement sensor 400 are installed inside the deposition chamber. The transfer controller 700 and the shutter controller 800 may either be installed inside or outside the deposition chamber.

The deposition source 100, the transfer unit 200, the shutter 300, and the thickness measurement sensor 400 may be placed at one side within the deposition chamber, and a substrate 500 may be placed at the other side. For example, if the deposition apparatus is designed to perform a vapor deposition process, the deposition source 100, the transfer unit 200, the shutter 300, and the thickness measurement sensor 400 can be placed in a lower part of the deposition chamber, and the substrate 500 can be placed in an upper part of the deposition chamber.

The deposition source 100 may emit or eject a deposition material that is to be deposited on a surface of the substrate 500. As shown in the figures, the deposition source 100 includes a deposition source holder 110 and a plurality of emission holes 120. The deposition source holder 110 contains the deposition material and includes a heater (not shown) for heating the deposition material. The heater is used to heat the deposition material that is provided in a solid or liquid state and produce deposition material in a gaseous state. As such, the deposition material in the gaseous state is emitted from the deposition source 100 through the emission holes 120. In the exemplary embodiment of FIG. 1, the deposition source holder 110 extends in a first direction, i.e., the shorter length corresponding to a width (W) of the substrate 500. Thus, the deposition source holder 110 may be shaped like, but not limited to, a rectangular cuboid or block.

Referring to FIG. 1, the emission holes 120 are formed on a surface of the deposition source 100 which faces the surface of the substrate 500 on which the deposition material is deposited. The emission holes 120 are arranged in the first direction. Here, the first direction is the same direction as the direction in which the deposition source holder 110 extends in dimension W. The emission holes 120 are typically arranged in a row or in multiple rows. As shown in FIG. 1, the emission holes 120 are all be circular. However, the disclosed technology is not limited thereto, and all of the emission holes 120 can be oval or polygonal. Alternatively, the emission holes 120 can have different shapes. In addition, the emission holes 120 may be formed in the same plane, or at least one of the emission holes 120 may be formed in a different plane. In FIG. 1, the emission holes 120 are spaced at regular intervals. However, the disclosed technology is not limited thereto, and the emission holes 120 can be spaced at irregular intervals.

The emission holes 120 can be arranged in the first direction over a length corresponding to either long or short sides of the substrate 500. In the exemplary embodiment of FIG. 1, the emission holes 120 are arranged in the first direction over a length corresponding to the width (W) of the substrate 500, and the width (W) of the substrate 500 corresponds to the short sides of the substrate 500.

The transfer unit 200 may be installed under the deposition source holder 110. The transfer unit 200 may move the deposition source 100 in a direction parallel to the surface of the substrate 500 and perpendicular to the first direction. Here, the first direction may be the same direction in which the deposition source holder 110 extends. In an exemplary embodiment, the deposition source 100 extends in the direction corresponding to the width (W) of the substrate 500 (and thus, in a direction parallel to the short sides of the substrate 500, that is, in a widthwise direction (W) of the substrate 500). In this configuration, the deposition source 100 deposits the deposition material on the surface of the substrate 500 by moving from under a first short side of the substrate 500 nearest a first edge to under a second short side of the substrate 500 nearest a second edge in a direction parallel to the long sides of the substrate 500, that is, in a lengthwise direction (L) of the substrate 500. In this way, the deposition source 100 can perform deposition by scanning the substrate 500 in a single pass or scanning the substrate 500 across multiple passes (by moving in a reciprocating manner). In this description, a configuration where the transfer unit 200 forms a thin film 600 on the substrate 500 by scanning the substrate 500 a predetermined number of times is described as an example. However, the disclosed technology is not limited to this example. In the exemplary embodiment of FIGS. 1 and 2, the deposition source 100 extends in the x direction parallel to the short sides of the substrate 500, the transfer unit 200 moves in a y direction parallel to the long sides of the substrate 500, and the deposition material is emitted or ejected in a z direction, so that the deposition material is deposited on the bottom surface of the substrate 500 forming one or more thin films 600.

The thickness measurement sensor 400 measures, in real time, the thickness of the deposition material deposited on the surface of the substrate 500. The thickness measurement sensor 400 generally extends in the same direction (i.e., the first direction) as the direction in which the deposition source 100 extends. In addition, the thickness measurement sensor 400 may be placed parallel to the deposition source 100 and move in the same direction as the direction in which the deposition source 100 moves. The thickness measurement sensor 400 can be integrated with the deposition source 100. In an exemplary embodiment, the thickness measurement sensor 400 is an ellipsometer.

As depicted, the thickness measurement sensor 400 includes a sensor holder 410, a light emitter 420, and a light receiver 430. The sensor holder 410 supports the light emitter 420 and the light receiver 430. The sensor holder 410 extends in the first direction and is shaped like a rectangular cuboid or block. The light emitter 420 and the light receiver 430 are formed on a surface of the sensor holder 410 which faces the surface of the substrate 500 on which the deposition material is deposited. The light emitter 420 and the light receiver 430 may be parallel to each other and may extend in the first direction to a length corresponding to the length of the short or long sides of the substrate 500. In the exemplary embodiment of FIG. 1, the light emitter 420 and the light receiver 430 may extend in the x direction to a length corresponding to the short sides of the substrate 500, that is, the width W of the substrate 500.

The light emitter 420 emits a ray of light (indicated by a solid line in FIG. 2) toward the thin film 600 deposited on the surface of the substrate 500, and the light receiver 430 receives the reflected light and measures the thickness (th) of the thin film 600 based on characteristics of the received light. Since the lengths of the light emitter 420 and the light receiver 430 correspond to the width (W) of the substrate 500, the thickness measurement sensor 400 can measure the thickness (th) of the thin film 600 in the first direction at a particular time. In addition, since the thickness measurement sensor 400, together with the deposition source 100, moves in a direction perpendicular to the first direction and parallel to the surface of the substrate 500, it can measure the thickness (th) of the thin film 600 on the surface of the substrate 500 by scanning the substrate 500 once. Alternatively, the thickness measurement sensor 400 can measure the thickness th of the thin film 600 more accurately by scanning the substrate 500 multiple times by moving in a reciprocating manner, i.e., passing over the substrate a first time in a given direction, reversing direction and then passing over the substrate again, and so forth.

Although not shown in the drawings, the transfer controller 700 may be integrated with or separated from the deposition source 100 or the transfer unit 200. The transfer controller 700 can adjust the speed of the transfer unit 200 moving across a distance of the substrate 500 according to a desired thickness (hereinafter, referred to as a deposition rate) of the deposition material deposited on the surface of the substrate 500 per unit of time. In an exemplary embodiment, when the deposition rate in a real deposition process is higher than a preset deposition rate, the transfer controller 700 can increase the speed of the transfer unit 200 movement. When the deposition rate in the real deposition process is lower than the preset deposition rate, the transfer controller 700 can reduce the speed of the transfer unit 200 movement. This will be described in greater detail below.

As shown in FIG. 3, the transfer controller 700 includes a deposition rate calculation part 710, a deposition rate storage part 720, a deposition rate comparison part 730, and a deposition rate compensation part 740.

The deposition rate calculation part 710 receives a measured thickness of the deposition material (i.e., the measured thickness (th) of the thin film 600) in the form of data from the thickness measurement sensor 400, calculates a deposition rate by dividing the received thickness (th) of the thin film 600 by a unit of time, and provides the calculated deposition rate to the deposition rate comparison part 730.

The deposition rate storage part 720 provides a preset deposition rate to the deposition rate comparison part 730. The preset deposition rate can be adjusted according to process conditions.

The deposition rate comparison part 730 receives the calculated deposition rate from the deposition rate calculation part 710 and the preset deposition rate from the deposition rate storage part 720, calculates a difference between the calculated deposition rate and the preset deposition rate, and provides the calculated difference to the deposition rate compensation part 740. In an exemplary embodiment, a difference value obtained by subtracting the preset deposition rate from the calculated deposition rate is provided in the form of data to the deposition rate compensation part 740.

The deposition rate compensation part 740 may increase or reduce the moving speed of the transfer unit 200 according to the difference between the calculated deposition rate and the preset deposition rate. In an exemplary embodiment, when the calculated deposition rate is higher than the preset deposition rate, the deposition rate compensation part 740 increases the moving speed of the transfer unit 200 by an amount corresponding to an absolute value of the difference between the calculated deposition rate and the preset deposition rate. When the calculated deposition rate is lower than the preset deposition rate, the deposition rate compensation part 740 reduces the moving speed of the transfer unit 200 by the amount corresponding to the absolute value of the difference between the calculated deposition rate and the preset deposition rate.

In an exemplary embodiment in which the moving speed of the transfer unit 200 is adjusted according to the deposition rate, when a value obtained by subtracting the preset deposition rate from a deposition rate at a certain point in time during a deposition process is a positive number. That is, when a deposition rate in a real deposition process is higher than the preset deposition rate, the transfer controller 700 increases the moving speed of the transfer unit 200. In this configuration, as an absolute value of the obtained difference value increases, the moving speed of the transfer unit 200 is increased by a greater amount. If the moving speed of the transfer unit 200 is increased as described above, a period of time during which the deposition source 100 scans the substrate 500 is reduced. This can result in a reduction in the thickness (i.e., the deposition rate) of the deposition material deposited on the surface of the substrate 500 per unit of time.

In another exemplary embodiment in which the moving speed of the transfer unit 200 is adjusted according to the deposition rate, when a value obtained by subtracting the preset deposition rate from a deposition rate at a certain point in time during a deposition process is a negative number, that is, when a deposition rate in a real deposition process is lower than the preset deposition rate, the transfer controller 700 may reduce the moving speed of the transfer unit 200. In this configuration, as an absolute value of the value obtained by subtracting the preset deposition rate from the deposition rate at the certain point in time during the deposition process increases, the moving speed of the transfer unit 200 may be reduced by a greater amount. If the moving speed of the transfer unit 200 is reduced as described above, a period of time during which the deposition source 100 scans the substrate 500 increases. This can result in an increase in the thickness (i.e., the deposition rate) of the deposition material deposited on the surface of the substrate 500 per unit of time.

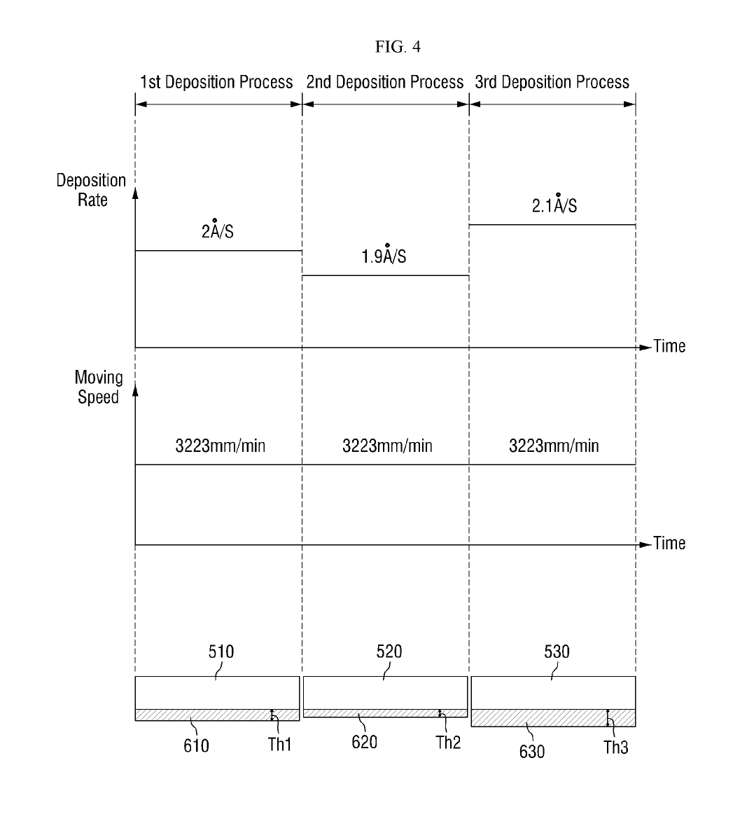

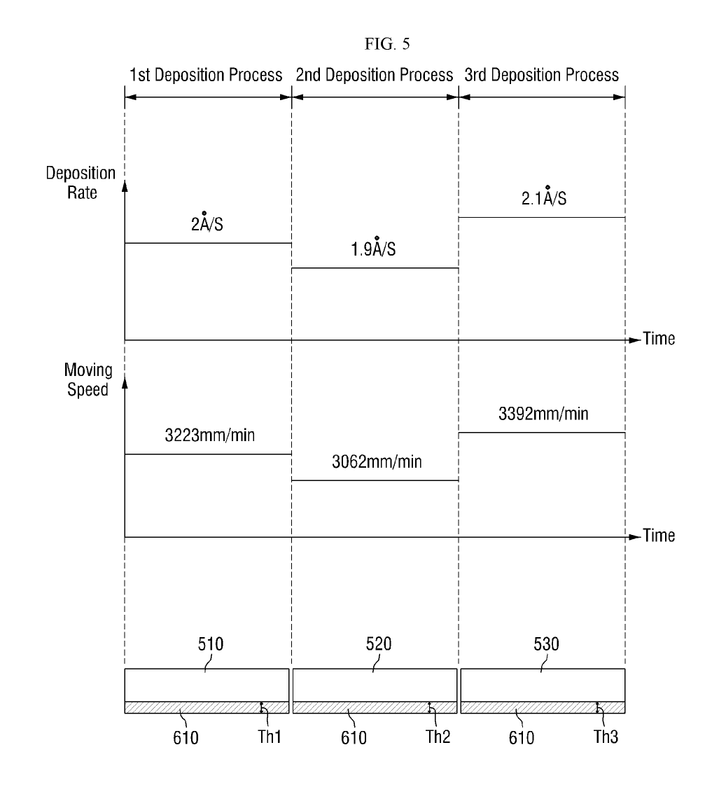

A specific example of the above description will now be described with reference to FIGS. 4 and 5. FIG. 4 is a schematic diagram showing respective thicknesses th of thin films 610 through 630 formed on a plurality of substrates 510 through 530 in a configuration where the moving speed of the transfer unit 200 included in the deposition apparatus of FIG. 1 is not adjusted. FIG. 5 is a schematic diagram showing respective thicknesses th of thin films 610 through 630 formed on a plurality of substrates 510 through 530 in a configuration where the moving speed of the transfer unit 200 included in the deposition apparatus of FIG. 1 is adjusted.

Referring to FIG. 4, the deposition apparatus according to the embodiment of FIG. 1 can be applied when thin films 610 through 630 are formed sequentially on a plurality of substrates 510 through 530, respectively.

For example, a first deposition process, a second deposition process, and a third deposition process may have different deposition rates. The difference in deposition rate may result from a change in process conditions when multiple deposition processes are performed or may result from a change in the properties of the deposition source 100 over time. Alternatively, the difference in deposition rate may result when each deposition process is performed differently by a different worker. In the exemplary embodiment of FIG. 4, the deposition rate in the first deposition process may be 2 Å/s, the deposition rate in the second deposition process may be 1.9 Å/s, and the deposition rate in the third deposition process may be 2.1 Å/s. In this configuration, if the moving speed of the transfer unit 200 is not adjusted, that is, is maintained at, e.g., 3223 mm/min in all of the first through third deposition processes as in the embodiment of FIG. 4, the thin films 610 through 630 formed on the substrates 510 through 530 input in the first through third deposition processes will all have different thicknesses. That is, since the moving speed of the transfer unit 200 fails to compensate for a different deposition rate in each deposition process, a third thin-film thickness (Th3) of the third thin film 630 formed on the third substrate 530 input in the third deposition process having a highest deposition rate is largest, and a second thin-film thickness (Th2) of the second thin film 620 formed on the second substrate 520 input in the second deposition process having a lowest deposition rate is smallest. In addition, a first thin-film thickness (Th1) of the first thin film 610 formed on the first substrate 510 input in the first deposition process having an intermediate deposition rate is between the second thin-film thickness Th2 and the third thin-film thickness Th3.

Referring to FIG. 5, each deposition process may have a different deposition rate as in FIG. 4. However, the difference in deposition rate can be compensated for by the moving speed of the transfer unit 200. That is, when the moving speed of the transfer unit 200 in the first deposition process having a deposition rate of 2 Å/s is 3223 mm/min, the moving speed of the transfer unit 200 in the second deposition process having a deposition rate of 1.9 Å/s is adjusted to 3062 mm/min which is slower than the moving speed of the transfer unit 200 in the first deposition process. In addition, the moving speed of the transfer unit 200 in the third deposition process having a deposition rate of 2.1 Å/s is adjusted to 3392 mm/min which is faster than the moving speed of the transfer unit 200 in the first deposition process. If the moving speed of the transfer unit 200 is adjusted in this way, the first through third thin-film thicknesses (Th1) through (Th3) of the first through third thin films 610 through 630 formed on the first through third substrates 510 through 530 will be equal. That is, the thicknesses of the thin films 610 through 630 formed on the substrates 510 through 530 input in the deposition processes can be adjusted to be equal by controlling the moving speed of the transfer unit 200 according to the deposition rate in each deposition process.

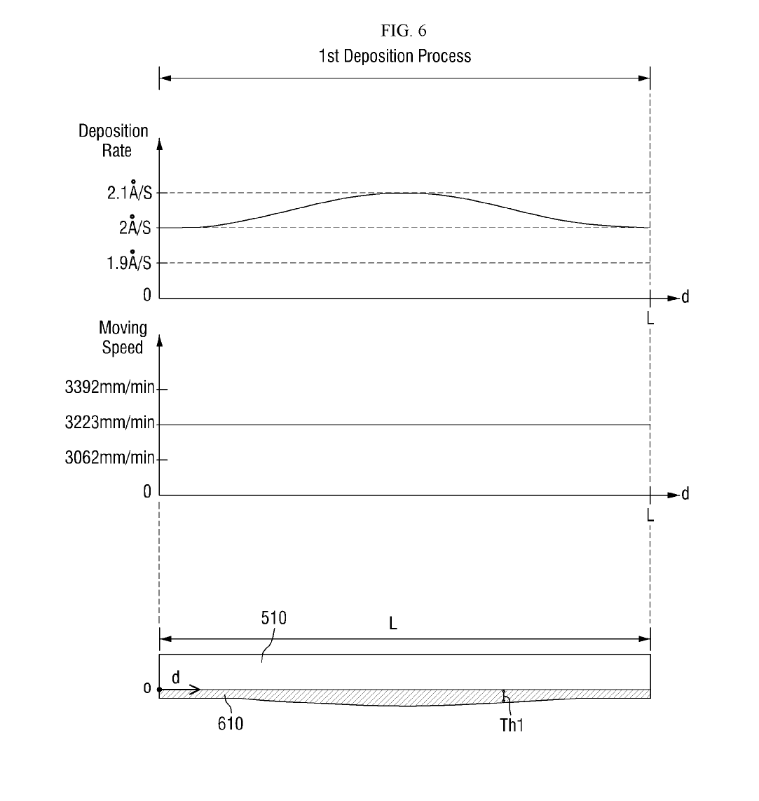

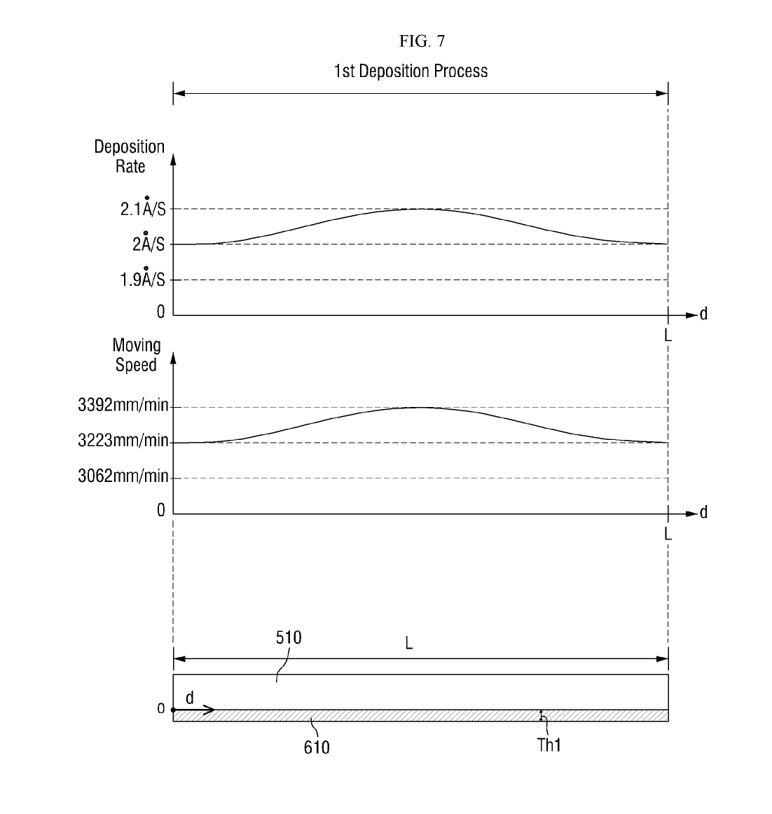

Another specific example of the above description will now be described with reference to FIGS. 6 and 7. FIG. 6 is a schematic diagram showing a thickness th of a thin film formed on one substrate 500 in a configuration where the moving speed of the transfer unit 200 included in the deposition apparatus of FIG. 1 is not adjusted. FIG. 7 is a schematic diagram showing a thickness (th) of a thin film formed on one substrate 500 in a configuration where the moving speed of the transfer unit 200 included in the deposition apparatus of FIG. 1 is adjusted.

The deposition apparatus according to the embodiment of FIG. 1 can be applied when a thin film 600 is formed on one substrate 500. That is, when a thin film 600 is formed on one substrate 500, the moving speed of the transfer unit 200 can be adjusted in real time. In the exemplary embodiment of FIGS. 6 and 7, as the transfer unit 200 scans the substrate 500 in a lengthwise direction (L) of the substrate 500, that is, in the y direction of FIG. 1, a deposition material is emitted onto the substrate 500.

Referring to FIG. 6, as a distance d in the lengthwise direction L of the substrate 500 increases, the deposition rate may increase and then decrease. That is, the deposition rate may be higher in a central portion of the substrate 500 than in an edge portion of the substrate 500. In an exemplary embodiment of the first deposition process illustrated in FIG. 6, when the transfer unit 200 starts from a position corresponding to an end of the substrate 500, the deposition rate is 2 Å/s. However, as the transfer unit 200 moves to a position corresponding to the central portion of the substrate 500, the deposition rate will increase up to 2.1 Å/s. Then, when the transfer unit 200 arrives at a position corresponding to the other end of the substrate 500 which is opposite the end of the substrate 500, the deposition rate is reduced again to 2 Å/s. That is, a graph of the deposition rate with respect to the distance d is in the shape of a gentle hill. In this configuration, if the moving speed of the transfer unit 200 is not adjusted, that is, is maintained at, e.g., 3223 mm/min as in the embodiment of FIG. 6, a first thin-film thickness (Th1) of a first thin film 610 formed on a first substrate 510 will not be uniform. That is, the first thin-film thickness (Th1) will be relatively greater in the central portion of the first substrate 510 than in the edge portion of the first substrate 510.

Referring to FIG. 7, the deposition rate in the first deposition process may be as shown in FIG. 6. However, the deposition rate can be compensated in real time by the moving speed of the transfer unit 200. That is, when the transfer unit 200 starts from a position corresponding to an end of the substrate 500, the moving speed of the transfer unit 200 is 3223 mm/min. However, as the transfer unit 200 moves to a position corresponding to the central portion of the substrate 500, the moving speed of the transfer unit 200 may increase up to 3392 mm/min. Then, when the transfer unit 200 arrives at a position corresponding to the other end of the substrate 500, the moving speed of the transfer unit 200 may be reduced again to 3223 mm/min. That is, similarly to the graph of the deposition rate with respect to the distance d, a graph of the moving speed of the transfer unit 200 with respect to the distance d may be in the shape of a gentle hill. If the moving speed of the transfer unit 200 is adjusted in this way, a first thin-film thickness (Th1) of a first thin film 610 formed on a first substrate 510 may be uniform along the lengthwise direction L of the first substrate 510. That is, a thickness (th) of a thin film formed on one substrate 500 input in one deposition process can be adjusted to be uniform by controlling the moving speed of the transfer unit 200 according to a deposition rate in the deposition process.

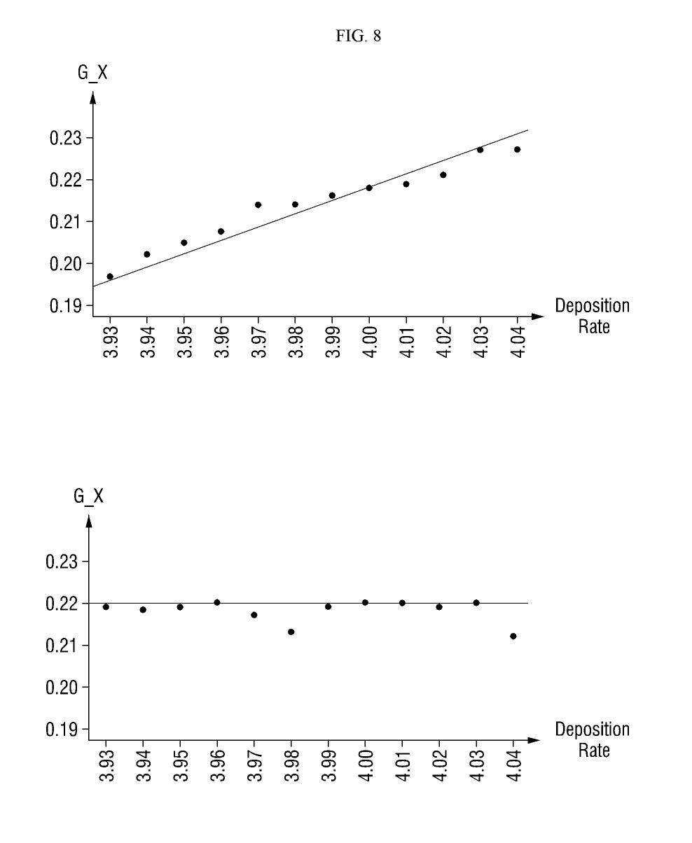

If a thin film 600 having a uniform thickness is formed by adjusting the moving speed of the transfer unit 200 as described above, characteristics related to the thin film 600 can be improved. A specific example for this will now be described with reference to FIG. 8. FIG. 8 is a diagram illustrating an exemplary embodiment in which the deposition source 100 emits an organic material that forms a green light-emitting layer. Specifically, FIG. 8 shows graphs of a green color coordinate G_x of a green light-emitting layer with respect to deposition rate before and after the moving speed of the transfer unit 200 included in the deposition apparatus of FIG. 1 is adjusted.

An upper graph in FIG. 8 illustrates the green color coordinate G_x of the green light-emitting layer with respect to deposition rate in a configuration where the moving speed of the transfer unit 200 is not adjusted. While a desired green color coordinate G_x is 0.22, it can be seen that the green color coordinate G_x varies according to deposition rate. As apparent from the upper graph of FIG. 8, as the deposition rate increases, the green color coordinate G_x also increases. This is because an increase in the deposition rate leads to an increase in the thickness of the green light-emitting layer formed on a surface of a substrate 500.

A lower graph in FIG. 8 illustrates the green color coordinate G_x of the green light-emitting layer with respect to deposition rate in a configuration where the moving speed of the transfer unit 200 is adjusted. As apparent from the lower graph of FIG. 8, even if the deposition rate changes, the green color coordinate G_x does not deviate greatly from 0.22. This is because a change in the deposition rate is compensated for by the moving speed of the transfer unit 200, and thus, the thickness of the green light-emitting layer is adjusted to a desired thickness.

Referring back to FIGS. 1 through 3, the shutter 300 may be placed above the deposition source 100 to open or close at least part of an emission path of the deposition material. That is, the shutter 300 may adjust an emission region of the deposition material by opening or closing at least part of the emission path of the deposition material emitted from the deposition source 100. If the emission region of the deposition material is adjusted, the thickness th of the thin film 600 on the surface of the substrate 500 which corresponds to the adjusted emission region can be adjusted.

The shutter 300 may extend in the same direction (i.e., the first direction) as the direction in which the deposition source 100 extends. In addition, the shutter 300 may be placed parallel to the deposition source 100 and located above at least a side of the deposition source 100. Further, the shutter 300 can be integrated with the deposition source 100. The shutter 300 may be provided in a plurality. In an exemplary embodiment, two shutters 300 may be provided. In this configuration, one of the two shutters 300 may be placed above a side of the deposition source 100, and the other one may be placed above the other side of the deposition source 100. In this configuration, an emission path of the deposition material emitted from the emission holes 120 may be formed between the two shutters 300. That is, the two shutters 300 placed above the emission holes 120 may perform a blocking function, thereby defining a maximum emission region of the deposition material. Referring to FIG. 2, the maximum emission region may be defined by a first blocking plate holder 310a and a second blocking plate holder 310b which will be described later.

The shutter 300 may include a blocking plate holder 310 and a blocking plate 320. The blocking plate holder 310 supports the blocking plate 320. The blocking plate holder 310 may extend in the first direction to a length corresponding to the width W of the substrate 500 and may be placed parallel to the deposition source 100. The blocking plate holder 310 may be provided in a plurality. In the exemplary embodiment of FIGS. 1 and 2, two cuboid-shaped blocking plate holders 310, that is, the first blocking plate holder 310a and the second blocking plate holder 310b may be placed above both sides of the deposition source 100 to be symmetrical to each other.

The blocking plate 320 may substantially perform a function of adjusting the emission region of the deposition material. The blocking plate 320 may protrude from the blocking plate holder 310 in a direction toward the emission holes 120, thereby adjusting the emission region of the deposition material. For example, referring to FIG. 2, the blocking plate 320 may block part of the emission path (indicated by dotted lines in FIG. 2) of the deposition material, thereby reducing the emission region of the deposition material. The blocking plate 320 may protrude from the blocking plate holder 310 in a slidable manner. Alternatively, the blocking plate 320 may be in a folded state and may protrude as it is spread out. The blocking plate 320 can protrude toward the emission holes 120 in various ways.

The blocking plate 320 may be one of a plurality of blocking plates. In addition, one blocking plate holder 310 may include at least one blocking plate 320. In the exemplary embodiment of FIGS. 1 and 2, a first blocking plate 320a may be installed in the first blocking plate holder 310a, and a second blocking plate 320b may be installed in the second blocking plate holder 310b.

The blocking plate 320 may be installed on an inner surface of the blocking plate holder 310. Here, the inner surface of the blocking plate holder 310 may be a surface of the blocking plate holder 310 which faces the emission holes 120. In addition, the blocking plate 320 may be formed on any side of a virtual line that halves a length of the blocking plate holder 310. In the exemplary embodiment of FIG. 1, the first blocking plate 320a may be formed on a left side of the virtual line that halves the length of the first blocking plate holder 310a measured in the x direction, and the second blocking plate 320b may be formed on a right side of the virtual line that halves the length of the second blocking plate holder 310b measured in the x direction.

The blocking plate 320 may protrude from the inner surface of the blocking plate holder 310 toward the emission holes 120 and may protrude parallel to the surface of the substrate 500. In addition, if the blocking plate 320 is provided in a plurality, the plurality of blocking plates 320 may be formed in the same plane. In the exemplary embodiment of FIG. 1, the first blocking plate 320a and the second blocking plate 320b are formed in the same plane. However, the disclosed technology is not limited thereto, and the first blocking plate 320a and the second blocking plate 320b can be formed in different planes.

The blocking plate 320 may be plate-shaped. A side of the blocking plate 320 may be supported by the blocking plate holder 310, and the other side which is opposite the side of the blocking plate 320 may protrude toward the emission holes 120. In an exemplary embodiment, at least part of the other side of the blocking plate 320 can be bent. In the exemplary embodiment of FIG. 1, the first blocking plate 320a can be bent toward the first blocking plate holder 310a along the x direction, and the second blocking plate 320b may be bent toward the second blocking plate 320b along a-x direction.

Although not shown in the drawings, the shutter controller 800 may be integrated with or separated from the deposition source 100 or the shutter 300. The shutter controller 800 may control the shutter 300 according to a difference between a thickness of the deposition material measured by the thickness measurement sensor 400 and a preset thickness of the deposition material.

The shutter controller 800 may include a thickness calculation part 810, a thickness storage part 820, a thickness comparison part 830, and a thickness compensation part 840.

The thickness calculation part 810 may receive the measured thickness of the deposition material in the form of data from the thickness measurement sensor 400, calculate the measured thickness as a graph of the thin-film thickness (th) with respect to the distance d in the first direction, that is, in the widthwise direction (W) of the substrate 500, and provide the calculated thickness to the thickness comparison part 830.

The thickness storage part 820 may provide a preset thickness of the deposition material to the thickness comparison part 830. The preset thickness of the deposition material may be or may not be uniform across the entire substrate 500 depending on desired device characteristics.

The thickness comparison part 830 may receive the calculated thickness of the deposition material from the thickness calculation part 810 and the preset thickness of the deposition material from the thickness storage part 820, calculate a difference between the calculated thickness of the deposition material with respect to the distance d in the first direction and the preset thickness of the deposition material, and provide the calculated difference to the thickness compensation part 840. In an exemplary embodiment, a value obtained by subtracting the preset thickness of the deposition material from the calculated thickness of the deposition material with respect to the distance d in the first direction may be provided in the form of data to the thickness compensation part 840.

The thickness compensation part 840 may open or close the shutter 300 according to the difference between the calculated thickness of the deposition material with respect to the distance d in the first direction and the preset thickness of the deposition material.

In an exemplary embodiment in which the thin-film thickness (th) is adjusted to be uniform, when a value obtained by subtracting the preset thickness of the deposition material from a calculated thickness of the deposition material at a certain position which is separated from a side of the substrate 500 in the first direction by a certain distance is a positive number, that is, when the calculated thickness of the deposition material is greater than the preset thickness of the deposition material, the thickness compensation part 840 may close a portion of the emission path of the deposition material by controlling the blocking plate 320 which faces the certain position to protrude. Here, the blocking plate 320 which faces the certain position may be the blocking plate 320 located directly under the certain position. In this configuration, as an absolute value of the value obtained by subtracting the preset thickness of the deposition material from the calculated thickness of the deposition material increases, the blocking plate 320 may be controlled to protrude further. Accordingly, the blocking plate 320 can reduce the emission region of the deposition material by blocking more portions of the emission path of the deposition material. If the shutter 300 is closed as described above, an increase in the thickness (th) of the thin-film 600 formed on a portion of the surface of the substrate 500 which corresponds to the closed shutter 300 is reduced. As a result, the thin-film thickness (th) can be adjusted to be uniform.

In another exemplary embodiment in which the thin-film thickness (th) is adjusted to be uniform, when a value obtained by subtracting the preset thickness of the deposition material from a calculated thickness of the deposition material at a certain position which is separated from a side of the substrate 500 in the first direction by a certain distance is a negative number, that is, when the preset thickness of the deposition material is greater than the calculated thickness of the deposition material, the thickness compensation part 840 may open a portion of the emission path of the deposition material by inserting the blocking plate 320 which faces the certain position into the blocking plate holder 310 or folding the blocking plate 320. In this configuration, as an absolute value of the value obtained by subtracting the preset thickness of the deposition material from the calculated thickness of the deposition material increases, the blocking plate 320 may be inserted or folded more. Accordingly, the blocking plate 320 can increase the emission region of the deposition material by opening more portions of the emission path of the deposition material. If the shutter 300 is opened as described above, an increase in the thickness th of the thin film 600 formed on a portion of the surface of the substrate 500 which corresponds to the opened shutter 300 increases. As a result, the thin-film thickness (th) can be adjusted to be uniform.

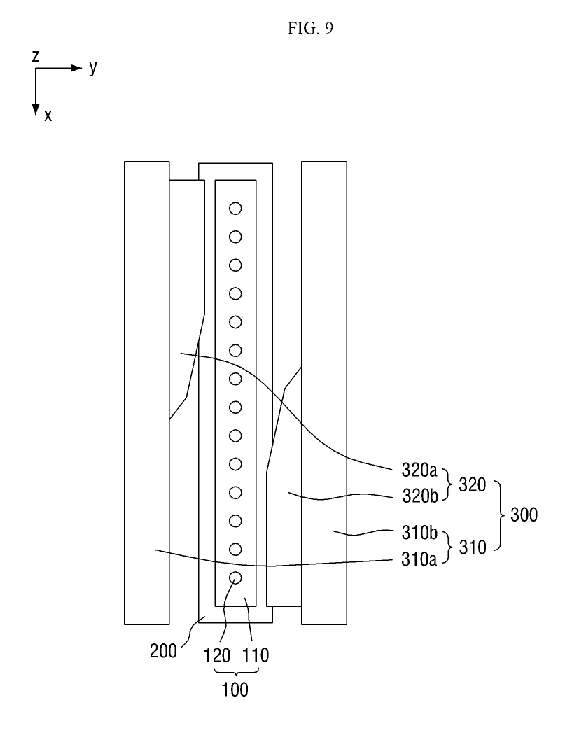

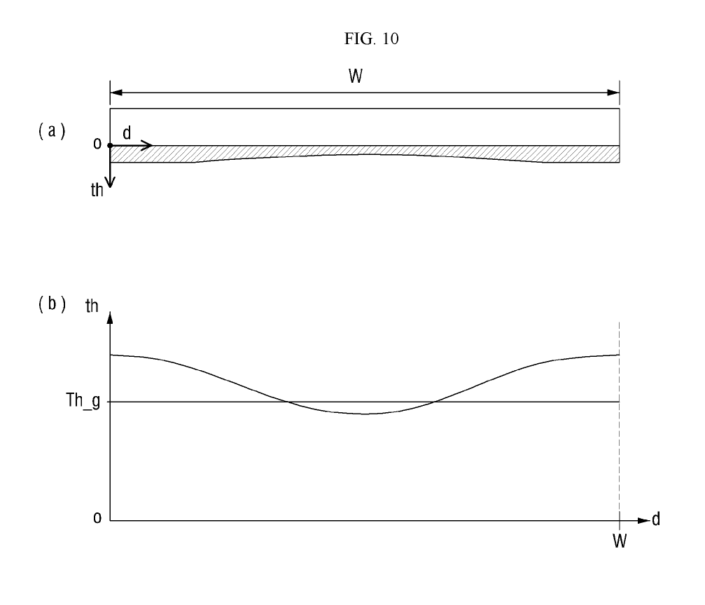

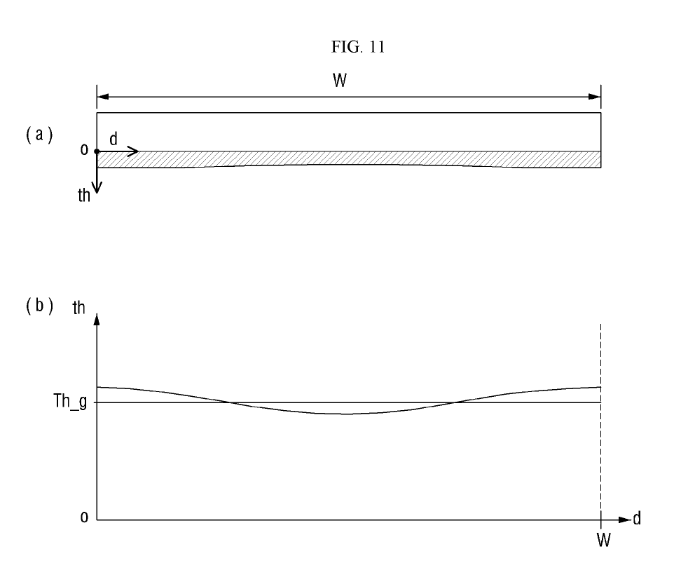

A specific example, i.e., a first application example of the above description will now be described with reference to FIGS. 9 through 11. The first application example is an example of adjusting a thin-film thickness (th) to be uniform. FIG. 9 is a plan view of a first application example of the deposition source 100, the transfer unit 200, and the shutter 300 included in the deposition apparatus of FIG. 1. FIG. 10 is a schematic diagram illustrating the thin-film thickness (th) with respect to the distance d before the shutter 300 of FIG. 9 is applied. FIG. 11 is a schematic diagram illustrating the thin-film thickness (th) with respect to the distance d after the shutter 300 of FIG. 9 is applied.

Referring to FIG. 10, a thickness (i.e., an uncompensated thickness) of a deposition material measured before the shutter 300 is applied may be in the shape of a wave along the first direction. That is, the uncompensated thickness of the deposition material measured at both ends of a substrate 500 shown in FIG. 10 may be greater than a preset thickness of the deposition material, and the uncompensated thickness of the deposition material measured in a central portion of the substrate 500 may be smaller than the preset thickness of the deposition material.

Therefore, the thin-film thickness (th) may be compensated as shown in FIG. 11 by applying the shutter 300 of FIG. 9. Specifically, the first blocking plate 320a and the second blocking plate 320b may block portions of an emission path of the deposition material which correspond to both ends of the substrate 500, thereby reducing a rate at which a thin film 600 is formed at both ends of the substrate 500. As a result, the thickness (i.e., a compensated thickness) of the deposition material measured after the shutter 300 of FIG. 9 is applied may overall be uniform compared with the uncompensated thickness of the deposition material. That is, the actual thickness of the deposition material can overall be adjusted to be close to a target thin-film thickness (Thg).

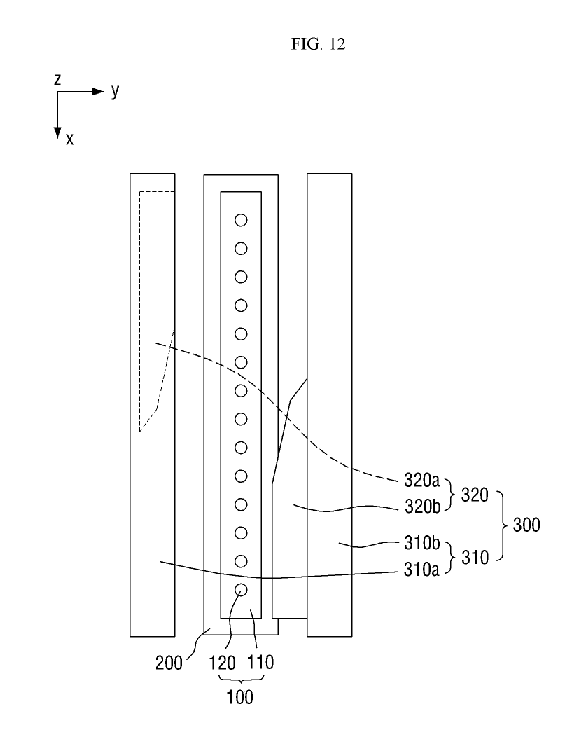

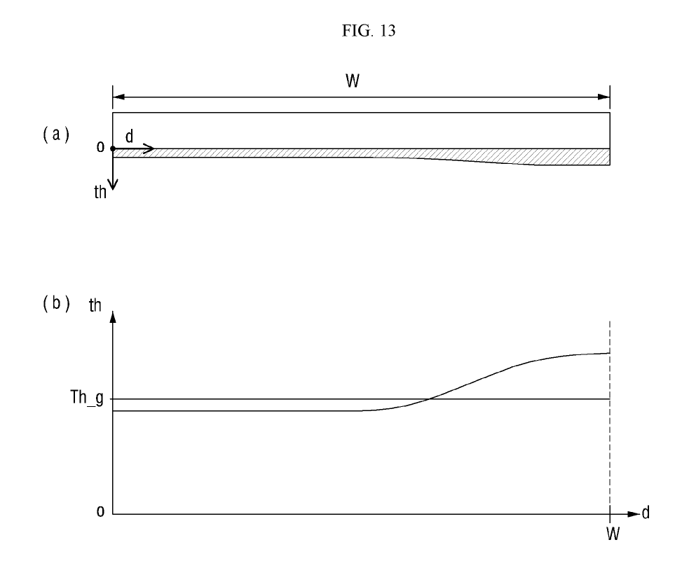

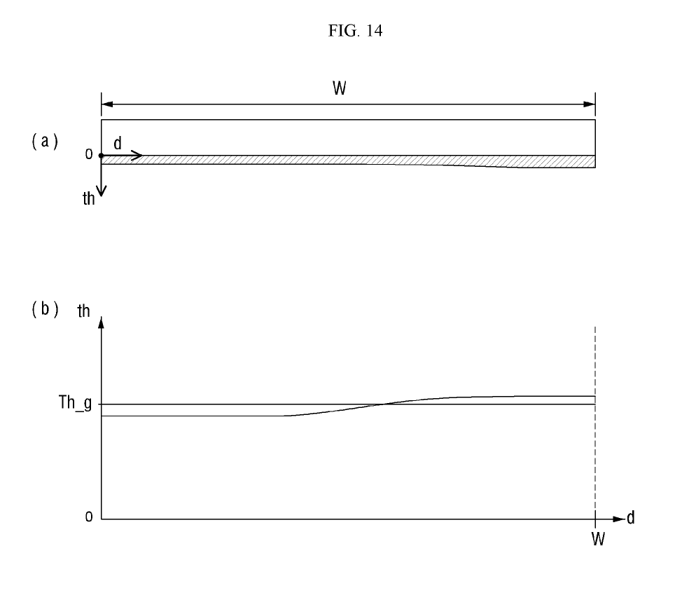

Another specific example, i.e., a second application example of the above description will now be described with reference to FIGS. 12 through 14. Like the first application example, the second application example is an example of adjusting a thin-film thickness (th) to be uniform. FIG. 12 is a plan view of a second application example of the deposition source 100, the transfer unit 200, and the shutter 300 included in the deposition apparatus of FIG. 1. FIG. 13 is a schematic diagram illustrating the thin-film thickness th with respect to the distance d before the shutter 300 of FIG. 12 is applied. FIG. 14 is a schematic diagram illustrating the thin-film thickness (th) with respect to the distance d after the shutter 300 of FIG. 12 is applied.

Referring to FIG. 13, a thickness (i.e., an uncompensated thickness) of a deposition material measured before the shutter 300 is applied may increase along the first direction. That is, the uncompensated thickness of the deposition material measured on a left side of a substrate 500 shown in FIG. 13 may be smaller than a preset thickness of the deposition material, and the uncompensated thickness of the deposition material measured on a right side of the substrate 500 may be greater than the preset thickness of the deposition material.

Therefore, the thin-film thickness th may be compensated as shown in FIG. 14 by applying the shutter 300 of FIG. 12. Specifically, the first blocking plate 320a may be inserted into the blocking plate holder 310, thereby opening a portion of an emission path of the deposition material which corresponds to the left side of the substrate 500. On the other hand, the second blocking plate 320b may block a portion of the emission path of the deposition material which corresponds to the right side of the substrate 500. As a result, a rate at which a thin film 600 is formed on the left side of the substrate 500 may be increased, whereas a rate at which the thin film 600 is formed on the right side of the substrate 500 is reduced. Therefore, the thickness (i.e., a compensated thickness) of the deposition material measured after the shutter 300 of FIG. 12 is applied may overall be uniform compared with the uncompensated thickness of the deposition material.

As described above, the deposition apparatus according to the current embodiment can adjust a thickness (th) of a thin film formed on a surface of a substrate 500 during a deposition process without releasing vacuum. In addition, since the thickness (th) of the thin film is compensated in real time during the deposition process, a desired thin-film thickness (th) can be obtained easily. In particular, the thin-film thickness (th) with respect to the lengthwise direction L of the substrate can be adjusted by controlling the moving speed of the transfer unit 200, and the thin-film thickness (th) with respect to the widthwise direction (W) of the substrate can be adjusted by controlling the shutter 300. Therefore, the overall thickness (th) of the thin film formed on the surface of the substrate 500 can be adjusted easily by controlling both the moving speed of the transfer unit 200 and the shutter 300.

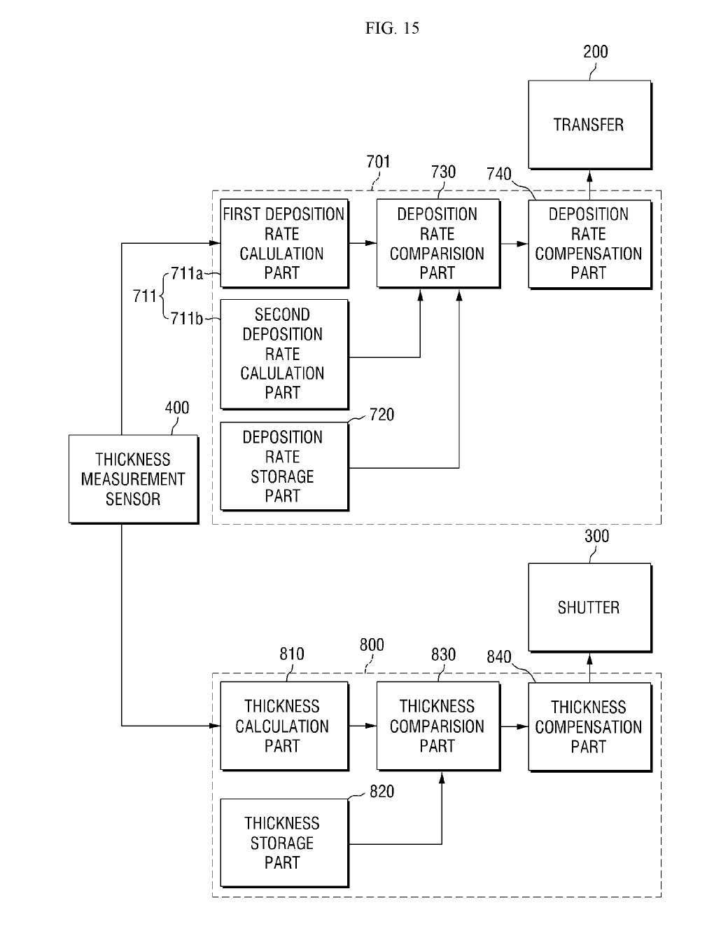

FIG. 15 is a block diagram of a transfer controller 701 and a shutter controller 800 included in a deposition apparatus according to another embodiment of the disclosed technology. For simplicity, elements substantially identical to those of FIG. 3 are indicated by like reference numerals, and thus a repetitive description thereof will be omitted.

Referring to FIG. 15, a deposition rate calculation part 711 may include a first deposition rate calculation part 711a which calculates a first deposition rate in a first time section and a second deposition rate calculation part 711b which calculates a second deposition rate in a second time section. In an exemplary embodiment, the second time section may be included in the first time section. In addition, a deposition rate comparison part 730 may calculate a first difference between the first deposition rate and a preset deposition rate and a second difference between the second deposition rate and the preset deposition rate. A deposition rate compensation part 740 may increase or reduce a moving speed of a transfer unit 200 according to the first difference and the second difference.

As described above, the transfer controller 701 of the deposition apparatus according to the current embodiment can adjust the moving speed of the transfer unit 200 by reflecting the deposition rates in the two different time sections.

The deposition apparatus according to the current embodiment will now be described in greater detail using an exemplary embodiment in which the transfer unit 200 forms a thin film 600 on a substrate 500 by scanning the substrate 500 back and forth twice. Since the transfer unit 200 scans the substrate 500 back and forth twice, it makes a total of four one-way scans. Here, it is assumed that the transfer unit 200 moves at a constant speed during each one-way scan. During a first scan of the transfer unit 200, the transfer unit 200 may move at a preset speed. During a second scan of the transfer unit 200, the moving speed of the transfer unit 200 may be adjusted by reflecting a deposition rate during the first scan of the transfer unit 200. During a third scan of the transfer unit 200, the moving speed of the transfer unit 200 may be adjusted by reflecting a deposition rate during the second scan of the transfer unit 200. During a fourth scan of the transfer unit 200, that is, during a last scan of the transfer unit 200, the moving speed of the transfer unit 200 may be adjusted by calculating two deposition rates during the third scan of the transfer unit 200 and reflecting all of the two deposition rates. Here, one of the two deposition rates may be a deposition rate calculated in the entire time section during the third scan of the transfer unit 200, and the other one may be a deposition rate calculated in a part of the time section during the third scan of the transfer unit 200. If the moving speed of the transfer unit 200 is adjusted by reflecting deposition rates in two different time sections as described above, a thickness of the thin film 600 formed on a surface of the substrate 500 can be adjusted more easily.

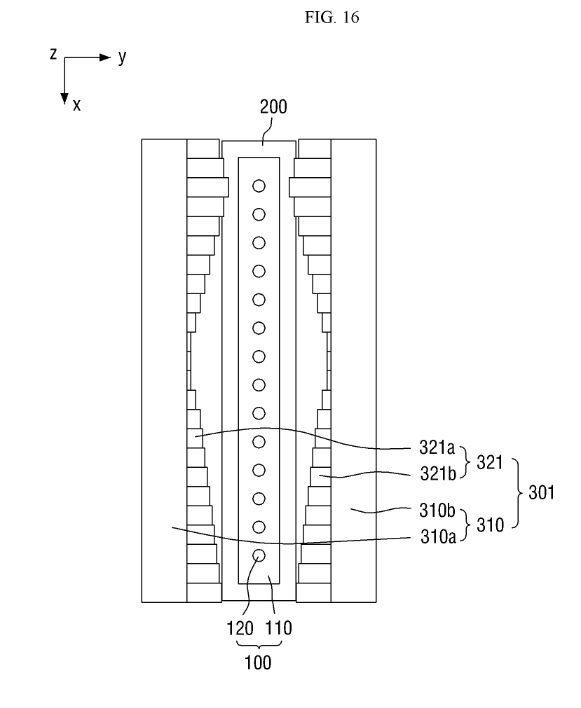

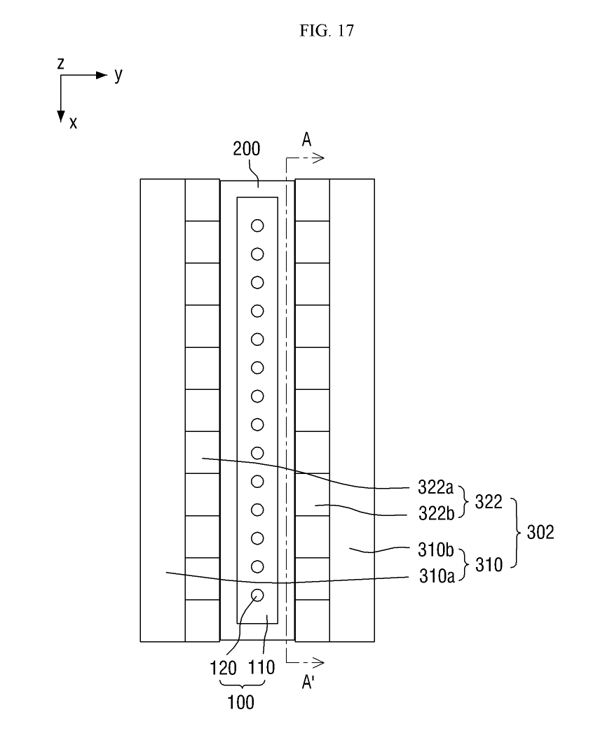

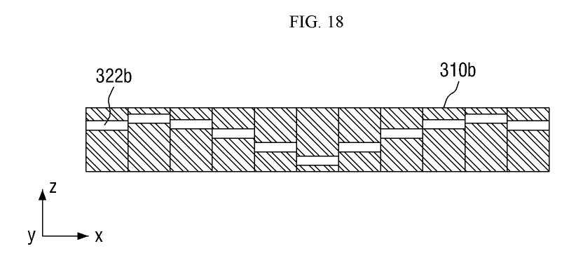

FIGS. 16 and 17 are plan views of deposition sources 100, transfer units 200, and shutters 301 and 302 included in deposition apparatuses according to other embodiments of the disclosed technology. FIG. 18 is a side view of the shutter 302 seen along the line A-A′ of FIG. 17. FIGS. 16 and 17 show the shutters 301 and 302 for compensating the uncompensated thickness of the deposition material shown in FIG. 10. If the shutters 301 and 302 of FIGS. 16 and 17 are applied, a thin-film thickness (th) can be adjusted to be uniform like the compensated thickness of the deposition material shown in FIG. 11. For simplicity, elements substantially identical to those of FIG. 9 are indicated by like reference numerals, and thus a repetitive description thereof will be omitted.

The shutter 301 of the deposition apparatus according to the embodiment of FIG. 16 may include a plurality of blocking plates 321 arranged in the first direction. The blocking plates 321 may be controlled individually to open or close corresponding portions of an emission path of a deposition material. In an exemplary embodiment, at least two of the blocking plates 321 may protrude different distances, thereby adjusting an emission region of the deposition material. In another exemplary embodiment, a plurality of first blocking plates 321a installed in a first blocking plate holder 310a may be symmetrical to a plurality of second blocking plates 321b installed in a second blocking plate holder 310b.

The shutter 302 of the deposition apparatus according to the embodiment of FIG. 17, like the shutter 301 of the deposition apparatus of FIG. 16, may include a plurality of blocking plates 322 arranged in the first direction. However, the blocking plates 322 may protrude the same distance from a blocking plate holder 310 toward emission holes 120. In an exemplary embodiment, a plurality of first blocking plates 322a installed in a first blocking plate holder 310a and a plurality of second blocking plates 322b installed in a second blocking plate holder 310b may all protrude the same distance toward the emission holes 120 and may be symmetrical to each other. However, referring to FIG. 18, at least two of the blocking plate 322 may have different heights. Here, a height may be a distance in the z direction from a bottom surface of the blocking plate holder 310. That is, some relatively high blocking plates 322 can reduce an emission angle of a deposition material, and the other relatively low blocking plates 322 can increase the emission angle of the deposition material.

A thin film deposition method according to an embodiment of the disclosed technology will now be described with reference to FIGS. 1 through 3. For simplicity, a repetitive description of features and aspects identical to those of the above-described deposition apparatuses will be omitted.

The deposition method according to the current embodiment may include emitting a deposition material, which is to be deposited on a surface of a substrate 500, using a deposition source 100, measuring a thickness of the deposition material deposited on the surface of the substrate 500, and adjusting a moving speed of the deposition source 100 according to the thickness of the deposition material deposited on the surface of the substrate 500 per unit of time. In an exemplary embodiment, when the thickness of the deposition material deposited on the surface of the substrate 500 per unit of time is greater than a preset value, the moving speed of the deposition source 100 may be increased. When the thickness of the deposition material deposited on the surface of the substrate 500 per unit of time is smaller than the preset value, the moving speed of the deposition source 100 may be reduced.

A thin film deposition method according to another embodiment of the disclosed technology will now be described with reference to FIGS. 1 through 3 and 5. For simplicity, a repetitive description of features and aspects identical to those of the above-described deposition apparatuses will be omitted.

The deposition method according to the current embodiment may include forming a first thin film 610 on a first substrate 510 by moving a deposition source 100 at a first moving speed and forming a second thin film 620, which has the same thickness as the first thin film 610, on a second substrate 520 by moving the deposition source 100 at a second moving speed which is different from the first moving speed.

Referring to FIG. 5, in a first deposition process, the deposition source 100 may form the first thin film 610 on the first substrate 510 by moving at 3223 mm/min. In a second deposition process, the deposition source 100 may form the second thin film 620, which has the same thickness as the first thin film 610, on the second substrate 520 by moving at 3062 mm/min.

Various embodiments of the disclosed technology provide at least one of the following advantages.

That is, a thickness of a thin film deposited on a surface of a substrate can be adjusted during a deposition process without release of vacuum.

In addition, a desired thin-film thickness can be obtained easily by compensating the thickness of the thin film in real time during the deposition process.

Furthermore, the overall thickness of the thin film formed on the surface of the substrate can be adjusted easily by controlling both a moving speed of a transfer unit and a shutter.

However, the effects of the disclosed technology are not restricted to the one set forth herein. The above and other effects of the disclosed technology will become more apparent to one of daily skill in the art to which the disclosed technology pertains by referencing the claims.

While the present invention has been particularly shown and described with reference to exemplary embodiments thereof, it will be understood by those of ordinary skill in the art that various changes in form and details may be made therein without departing from the spirit and scope of the present invention as defined by the following claims. It is therefore desired that the present embodiments be considered in all respects as illustrative and not restrictive, reference being made to the appended claims rather than the foregoing description to indicate the scope of the invention.

What is claimed is:

1. A thin film deposition apparatus, comprising:
a deposition source configured to emit a deposition material that is to be deposited on a surface of a substrate;
a transfer unit configured to move the deposition source;
a thickness measurement sensor configured to measure a thickness of the deposition material deposited on the surface of the substrate; and
a transfer controller configured to adjust a moving speed of the transfer unit according to the thickness of the deposition material deposited on the surface of the substrate per unit of time.

2. The thin film deposition apparatus of claim 1, wherein the transfer controller increases the moving speed of the transfer unit when the thickness of the deposition material deposited on the surface of the substrate per unit of time is greater than a preset value and reduces the moving speed of the transfer unit when the thickness of the deposition material deposited on the surface of the substrate per unit of time is smaller than the preset value.

3. The thin film deposition apparatus of claim 1, wherein the transfer controller comprises:
a deposition rate calculation part configured to calculate a deposition rate by dividing the measured thickness of the deposition material by a unit of time;
a deposition rate storage part configured to store a preset deposition rate;
a deposition rate comparison part configured to calculate a difference between the calculated deposition rate and the preset deposition rate; and
a deposition rate compensation part configured to increase or reduce the moving speed of the transfer unit according to the calculated difference.

4. The thin film deposition apparatus of claim 3, wherein the deposition rate compensation part increases the moving speed of the transfer unit when the calculated deposition rate is higher than the preset deposition rate and reduces the moving speed of the transfer unit when the calculated deposition rate is lower than the preset deposition rate.

5. The thin film deposition apparatus of claim 3, wherein the deposition rate calculation part comprises:
a first deposition rate calculation part configured to calculate a first deposition rate in a first time section; and
a second deposition rate calculation part configured to calculate a second deposition rate in a second time section,
wherein the deposition rate comparison part calculates a first difference between the first deposition rate and the preset deposition rate and a second difference between the second deposition rate and the preset deposition rate, and the deposition rate compensation part increases or reduces the moving speed of the transfer unit according to the first difference and the second difference.

6. The thin film deposition apparatus of claim 5, wherein the second time section is included in the first time section.

7. The thin film deposition apparatus of claim 1, wherein the deposition source extends in a first direction parallel to the surface of the substrate, and the transfer unit moves the deposition source in a direction parallel to the surface of the substrate and perpendicular to the first direction.

8. The thin film deposition apparatus of claim 7, further comprising at least one shutter adjusting an emission region of the deposition material by opening or closing at least part of an emission path of the deposition material.

9. The thin film deposition apparatus of claim 8, wherein the shutter extends in the first direction, placed parallel to the deposition source, and is located above at least a side of the deposition source.

10. The thin film deposition apparatus of claim 9, wherein two shutters are provided, wherein one of the two shutters is located above a side of the deposition source, the other one of the two shutters is located above the other side of the deposition source, and the emission path of the deposition material is formed between the two shutters.

11. The thin film deposition apparatus of claim 8, wherein the shutter comprises:
at least one blocking plate holder extending in the first direction and placed parallel to the deposition source; and
at least one blocking plate protruding from the blocking plate holder toward emission holes.

12. The thin film deposition apparatus of claim 11, wherein the blocking plate is provided in a plurality, wherein the blocking plates are arranged in the first direction, and at least two of the blocking plates protrude different distances to adjust the emission region of the deposition material.

13. The thin film deposition apparatus of claim 8, wherein the shutter comprises a plurality of blocking plates placed parallel to the deposition source and arranged in the first direction, wherein at least two of the blocking plates have different heights to adjust an emission angle of the deposition material.

14. The thin film deposition apparatus of claim 8, further comprising a shutter controller configured to control the shutter according to the measured thickness of the deposition material.

15. The thin film deposition apparatus of claim 14, wherein the shutter controller comprises:
a thickness calculation part configured to calculate the measured thickness of the deposition material;
a thickness storage part configured to store a preset thickness of the deposition material;
a thickness comparison part configured to calculate a difference between the calculated thickness of the deposition material and the preset thickness of the deposition material; and
a thickness compensation part configured to open or close the shutter according to the calculated difference.

16. The thin film deposition apparatus of claim 15, wherein the thickness compensation part closes the shutter facing the measured deposition material when the calculated thickness of the deposition material is greater than the preset thickness of the deposition material and opens the shutter facing the measured deposition material when the preset thickness of the deposition material is greater than the calculated thickness of the deposition material.

17. A thin film deposition apparatus, comprising:
a deposition source configured to emit a deposition material that is to be deposited on a surface of a substrate;
at least one shutter configured to adjust an emission region of the deposition material by opening or closing at least part of an emission path of the deposition material;
a thickness measurement sensor configured to measure a thickness of the deposition material deposited on the surface of the substrate; and
a shutter controller configured to control the shutter according to the measured thickness of the deposition material.

18. The thin film deposition apparatus of claim 17, further comprising:
a transfer unit configured to move the deposition source; and
a transfer controller configured to adjust a moving speed of the transfer unit according to the thickness of the deposition material deposited on the surface of the substrate per unit of time.

19. The thin film deposition apparatus of claim 18, wherein the transfer controller increases the moving speed of the transfer unit when the thickness of the deposition material deposited on the surface of the substrate per unit of time is greater than a preset value and reduces the moving speed of the transfer unit when the thickness of the deposition material deposited on the surface of the substrate per unit of time is smaller than the preset value.

20. The thin film deposition apparatus of claim 18, wherein the shutter controller closes the shutter facing the measured deposition material when the measured thickness of the deposition material is greater than the preset value and opens the shutter facing the measured deposition material when the measured thickness of the deposition material is smaller than the preset value.

21. A thin film deposition method, comprising:
emitting a deposition material, which is to be deposited on a surface of a substrate, using a deposition source;
measuring a thickness of the deposition material deposited on the surface of the substrate;
moving the deposition source across the substrate; and
adjusting the speed of the deposition source movement according to the thickness of the deposition material deposited on the surface of the substrate per unit of time.

22. The deposition method of claim 21, wherein the speed of the deposition source movement is increased when the thickness of the deposition material deposited on the surface of the substrate per unit of time is greater than a preset value, and the speed of the deposition source movement is reduced when the thickness of the deposition material deposited on the surface of the substrate per unit of time is smaller than the preset value.

23. A deposition method, comprising:
forming a first thin film on a first substrate by moving a deposition source at a first speed; and
forming a second thin film, which has the same thickness as the first thin film, on a second substrate by moving the deposition source at a second speed which is different from the first speed.
